(19) United States
(12) Patent Application Publication
(10) Pub. No.: US 2020/0181762 A1
(43) Pub. Date: Jun. 11, 2020

(54) ALUMINUM ALLOY SPUTTERING TARGET

(71) Applicant: KOBELCO RESEARCH INSTITUTE, INC., Kobe-shi (JP)

(72) Inventor: Hiroyuki OKUNO, Takasago-shi (JP)

(73) Assignee: KOBELCO RESEARCH INSTITUTE, INC., Kobe-shi (JP)

(21) Appl. No.: 16/464,544

(22) PCT Filed: Oct. 26, 2017
(86) PCT No.: PCT/JP2017/038667

§ 371 Date: May 28, 2019

(51) Int. Cl. C23C 14/34; C22C 21/00; H01L 29/45; G02F 1/1343; H01J 37/34

(52) U.S. Cl. CPC C23C 14/3414; C22C 21/00; H01J 37/3426; G02F 1/13439; H01L 29/458

(57) ABSTRACT

Disclosed is an aluminum alloy sputtering target containing 0.01 atomic % to 0.04 atomic % in total of at least one element selected from the group consisting of Ni, Cr, Fe, Co and Cu, and 0.01 atomic % to 0.06 atomic % in total of at least one element selected from rare earth elements other than La, the balance being Al and inevitable impurities.

### TECHNICAL FIELD

The present disclosure relates to an aluminum alloy sputtering target which is used to form electrodes of thin film transistors for display devices such as a liquid crystal display and a MEMS display.

### BACKGROUND ART

An aluminum alloy thin film is used as scanning and signal electrodes of display devices such as a liquid crystal display since it has low electric resistance and is easily processed by etching. The aluminum alloy thin film is generally formed by a sputtering method using a sputtering target.

A vacuum deposition method has been known as a main film formation technique of a metal thin film, other than the sputtering method. The sputtering method has the merit of being capable of forming a thin film with the same composition as that of the sputtering target compared with a method such as the vacuum deposition method. From an industrial point of view, the sputtering method is an excellent film formation technique in terms of being capable of stably forming a film on a large area.

It has been known, as an aluminum alloy sputtering target used in the sputtering method, for example, pure Al or an aluminum alloy such as Al—Nd. Patent Document 1 discloses an Al—(Ni,Co)—(La,Nd)-based alloy target material used as an electrode of a liquid crystal display. It is disclosed that the target material of Patent Document 1 can reduce a phenomenon called splash in which a part of the target material is overheated due to insufficient cooling caused by defects and turns into a liquid phase, thus adhering to a substrate.

### PRIOR ART DOCUMENT

### Patent Document

Patent Document 1: JP 2011-106025 A

### SUMMARY OF THE INVENTION

### Problems to be Solved by the Invention

The aluminum alloy sputtering target is increasing in size in response to the upsizing of a substrate used for liquid crystal displays. When thin films for electrode of display devices were mass-produced using a conventional aluminum alloy sputtering target, including those mentioned in Patent Document 1, there arose a problem of the occurrence of a phenomenon in which thick film deposits peel off as flakes from a wall surface of a sputtering chamber due to a difference in thermal expansion coefficient with an inner wall material of the sputtering chamber.

There was a problem that a decrease in production yield is caused by adhesion of flakes to a panel substrate equipped with a display device, or performing maintenance such as cleaning of the inner wall of the sputtering chamber in order to prevent adhesion of flakes.

Embodiments of the present invention have been made so as to solve this problem, and it is an object thereof to provide an aluminum alloy sputtering target which has the same level of conductivity as that of a conventional aluminum alloy sputtering target and can reduce the generation of flakes.

### Means for Solving the Problems

An aluminum alloy sputtering target according to an embodiment of the present invention, which can solve the above-mentioned problem, contains 0.01 atomic % to 0.04 atomic % in total of at least one element selected from the group consisting of Ni, Cr, Fe, Co and Cu, and 0.01 atomic % to 0.06 atomic % in total of at least one element selected from rare earth elements other than La, the balance being Al and inevitable impurities.

In a preferred embodiment of the present invention, the rare earth elements are Y, Ce, Pr, Pm, Sm, Eu, Gd, Tb, Dy and Yb.

In a preferred embodiment of the present invention, the aluminum alloy sputtering target contains 0.01 atomic % to 0.03 atomic % in total of at least one element selected from the group consisting of Ni, Cr, Fe and Co, and 0.03 atomic % to 0.05 atomic % in total of at least one element selected from the group consisting of Y, Ce, Pr, Pm, Sm, Eu, Gd, Tb, Dy and Yb.

### Effects of the Invention

According to the embodiments of the present invention, it is possible to provide an aluminum alloy sputtering target which has the same level of conductivity as that of a conventional aluminum alloy sputtering target and can reduce the generation of flakes.

### MODE FOR CARRYING OUT THE INVENTION

The following embodiments exemplify an aluminum alloy sputtering target for embodying the technical idea of the present invention and do not limit the present invention to the followings. The embodiments are intended to illustrate, and not intended to limit the technical scope of the present invention thereto, unless otherwise specified.

The inventors have intensively studied and found that, as illustrated in detail below, it is possible to have the same level of conductivity as that of a conventional aluminum alloy sputtering target and to suppress the generation of flakes by adding a small amount of at least one element selected from the group consisting of Ni, Cr, Fe, Co and Cu, which is solid-soluted or which could slightly precipitate an Al—Ni, Al—Cr, Al—Fe, Al—Co or Al—Cu-based intermetallic compound, as well as a small amount of a rare earth element, which is solid-soluted or which could slightly precipitate an Al-rare earth-based intermetallic compound, more specifically, by adding 0.01 atomic % to 0.04 atomic % in total of at least one element selected from the group consisting of Ni, Cr, Fe, Co and Cu, and 0.01 atomic % to 0.06 atomic % in total of at least one element selected from rare earth elements other than La, and constituting the balance with Al and inevitable impurities, thus completing the present invention.

No attention was paid on the composition range containing at least one element selected from the group consisting of Ni, Cr, Fe, Co and Cu and at least one element selected from rare earth elements other than La since sufficient amounts of an Al—Ni or Co-based intermetallic compound and an Al—Nd or Al—La-based intermetallic compound cannot be obtained in an Al—(Ni or Co)—(Nd or La) alloy sputtering target of JP 2011-106025 A.

In the present specification, “aluminum alloy sputtering target” is a concept encompassing a sputtering target which further contains additive elements in a relatively small amount, for example, about 0.1% by mass or less in total. In the present specification, “aluminum alloy thin film” is a concept encompassing a sputtered thin film which further contains additive elements in a relatively small amount, for example, about 0.1% by mass or less in total.

An aluminum alloy sputtering target according to embodiments of the present invention will be described in detail below.

The aluminum alloy sputtering target according to an embodiment of the present invention contains 0.01 atomic % to 0.04 atomic % in total of at least one element selected from the group consisting of Ni, Cr, Fe, Co and Cu, and 0.01 atomic % to 0.06 atomic % in total of at least one element selected from rare earth elements other than La, the balance being Al and inevitable impurities. First, this composition will be described in detail.

### 1. Composition

### (1) Ni, Cr, Fe, Co and Cu

The content of at least one element selected from the group consisting of Ni, Cr, Fe, Co and Cu is 0.01 atomic % to 0.04 atomic % in total. The solid solubility limit of Ni, Cr, Fe, Co and Cu in Al varies depending on literatures, but is about 0.01 atomic % to 0.04 atomic % Namely, all of Ni, Cr, Fe, Co and Cu contained are solid-soluted in Al, or a small amount of the total amount of Ni, Cr, Fe, Co and Cu are segregated at a grain boundary of an aluminum crystal structure as an Al—Ni, Al—Cr, Al—Fe, Al—Co or Al—Cu-based intermetallic compound, and the remaining Ni, Cr, Fe, Co and Cu are solid-soluted in Al. Thereby, it is possible to maintain high conductivity which is the same level as that of a conventional aluminum alloy sputtering target and to reduce the generation of flakes. When intermetallic compounds of Ni, Cr, Fe, Co and Cu are precipitated, segregation at the grain boundary is due to the metallic bond radii of Ni, Cr, Fe, Co and Cu, which are 80 to 90% of the metallic bond radius of Al.

The additive element is preferably at least one element selected from the group consisting of Ni, Cr, Fe and Co. The content of at least one element selected from the group consisting of Ni, Cr, Fe, Co and Cu is preferably 0.01 atomic % to 0.03 atomic % in total. This is because the above-mentioned effect can be more reliably obtained.

If the content of at least one element selected from the group consisting of Ni, Cr, Fe, Co and Cu is less than 0.01 atomic % in total, the generation of flakes is not sufficiently reduced. Meanwhile, if the content of at least one element selected from the group consisting of Ni, Cr, Fe, Co or Cu exceeds 0.04 atomic % in total, the conductivity is degraded.

“Conductivity which is the same level as that of a conventional aluminum alloy sputtering target” means, for example, a case in which an electric resistivity of an aluminum thin film formed on a substrate by a sputtering method using an aluminum alloy sputtering target of interest is 1.05 times or less an electric resistivity of a pure aluminum thin film formed on a substrate by the same sputtering method using a pure aluminum sputtering target.

As shown in Examples mentioned later, the electric resistivity of an aluminum thin film formed using an aluminum alloy sputtering target of an embodiment of the present invention is sometimes less than one time the electric resistivity of a pure aluminum thin film formed on a substrate by the same sputtering method using a pure aluminum sputtering target. Namely, the conductivity of an aluminum thin film formed using an aluminum alloy sputtering target of an embodiment of the present invention is sometimes superior to the conductivity of an aluminum thin film formed using a pure aluminum target. The reason is presumed as follows, but the technical scope of the present invention is not limited thereby. As shown in Examples mentioned later, in the measurement of the electrical resistivity, the resistivity is measured after laminating a Mo thin film as upper and lower layers on an aluminum thin film and further heating, for example, at 450° C. The aluminum thin film formed using the aluminum alloy sputtering target of an embodiment of the present invention contains at least one element selected from the group consisting of Ni, Cr, Fe, Co and Cu, and thus has a grain size larger than that of the pure aluminum thin film. Therefore, the pure aluminum thin film having many crystal grain boundaries because of having a small crystal grain size has an electric resistance larger than that of the aluminum thin film formed using the aluminum alloy sputtering target of an embodiment of the present invention in some cases.

### (2) Rare Earth Elements

The content of rare earth elements is 0.01 atomic % to 0.06 atomic % in total. The solid solubility limit of rare earth elements in Al varies depending on literatures, but is about 0.01 atomic % Namely, all of rare earth elements are solid-soluted in Al, or a small amount of the total amount of rare earth elements are segregated within a grain of an aluminum crystal structure as an Al-rare earth element-based intermetallic compound, and many of the remaining rare earth elements are solid-soluted in Al as substitutional atoms. Due to the existence of a rare earth element as substitutional atom, dislocations accumulate during rolling mentioned later, and thus the generation of flakes is reduced. This is because the metallic bonding radii of the rare earth elements are 110% or more of that of Al. Furthermore, rare earth elements are partially segregated at a grain boundary in a natural oxide film of Al on the surface, thus contributing to an improvement in oxide film strength.

Thereby, it is possible to maintain high conductivity which is the same level as that of a conventional aluminum alloy sputtering target and to reduce the generation of flakes.

Rare earth elements are preferably Y, Ce, Pr, Pm, Sm, Eu, Gd, Tb, Dy and Yb. The content of rare earth elements is preferably 0.03 atomic % to 0.05 atomic % in total. By setting the content of rare earth elements at 0.03 atomic % or more in total, the generation of flakes can be further reduced. Meanwhile, if the content of rare earth elements exceeds 0.05 atomic % in total, an excessive amount of a hard Al-rare earth elements-based intermetallic compound is precipitated, thus making it difficult to obtain the effect of reducing the generation of flakes. If the content of rare earth elements is less than 0.01 atomic % in total, the generation of flakes is not sufficiently reduced. Meanwhile, if the content of rare earth elements exceeds 0.06 atomic % in total, the conductivity is degraded.

As mentioned above, Ni, Cr, Fe, Co and Cu are precipitated at a grain boundary, thus contributing to an increase in strength. Meanwhile, rare earth elements form a substitutional solid solution in grains and are segregated at a grain boundary in an Al oxide film on the surface, thus reducing the generation of flakes. In this way, it has been found that the combination of Ni, Cr, Fe, Co or Cu and rare earth elements is optimum since they contribute to a reduction in the generation of flakes by different mechanisms, thus making it possible to obtain the effect of reducing the generation of flakes due to the summation of their respective effects.

### (3) Balance

The balance is Al and inevitable impurities. In a preferred embodiment, the content of the inevitable impurities is 0.01% by mass or less in total. The content of inevitable impurities was expressed in % by mass since it is usually managed in terms of a mass ratio in many cases. Examples of the inevitable impurities include Si, Mg, Mn, Ti and Zn.

### 2. Form of Aluminum Alloy Sputtering Target

The aluminum alloy sputtering target according to an embodiment of the present invention may have any shape possessed by a known aluminum alloy sputtering target. Examples of such a shape include a square, a rectangle, a circle, an ellipse, and a shape that forms a part of these shapes in the top view. The aluminum alloy sputtering target having such a shape may have any size. The size of the aluminum alloy sputtering target of an embodiment of the present invention can be exemplified by 100 mm to 4,000 mm in length, 100 mm to 3,000 mm in width and 5 mm to 35 mm in sheet thickness.

The aluminum alloy sputtering target of an embodiment of the present invention may have any surface properties possessed by a known aluminum alloy sputtering target. For example, the surface on which ions collide may be a mechanically finished surface subjected to cutting or the like. Preferably, the surface on which the ions collide is a polished surface.

For example, using the aluminum alloy sputtering target of an embodiment of the present invention, as follows, an aluminum thin film may be formed on a substrate by sputtering. The aluminum alloy sputtering target of an embodiment of the present invention is bonded to a backing plate of, for example, copper or a copper alloy using a brazing material. In this way, in a state of being bonded to the backing plate, the aluminum alloy sputtering target is attached to a sputtering apparatus which is a vacuum device.

### 3. Production Method

The aluminum alloy sputtering target of an embodiment of the present invention may be produced using a method for producing any known aluminum alloy sputtering target. A method for producing an aluminum alloy sputtering target of an embodiment of the present invention will be exemplified below.

### (1) Melt Casting

First, a blended raw material with a predetermined composition is prepared for melting. Al, Ni, Cr, Fe, Co, Cu and rare earth elements, and relative metal simple substances may be used, and an aluminum alloy containing at least one of Ni, Cr, Fe, Co, Cu and rare earth elements may be used, as raw materials constituting the blended raw material. In a case of using raw materials of the metal simple substances, each of an Al raw material, a Ni raw material, a Cr raw material, a Fe raw material, a Co raw material and a Cu raw material preferably has a purity of 99.9% by mass or more, and more preferably 99.95% by mass or more. Each of the raw materials of the rare earth elements preferably has a purity of 99% by mass or more, and more preferably 99.5% by mass or more. After melting the mixed raw material by vacuum melting and casting, an ingot with a predetermined composition is obtained.

The aluminum alloy sputtering target of an embodiment of the present invention has an advantage that the composition can be made uniform without using spray forming, in other words, even if vacuum melting is performed, since the total content of Ni, Cr, Fe, Co and Cu and the total content of rare earth elements are smaller than those of a conventional Al—(Ni, Cr, Fe, Co or Cu)-rare earth element sputtering target. However, this does not exclude melt casting by spray forming and an ingot may be obtained by performing spray forming. Instead of vacuum melting, melting may be performed in an inert atmosphere such as an argon atmosphere.

The inventors have confirmed that Since Ni, Cr, Fe, Co, Cu and rare earth elements have the high vapor pressure and their evaporation during melting is restrictive, the composition of the blended raw materials, the composition of the ingot obtained by melt casting, and the composition of the finally obtained aluminum alloy sputtering target are substantially the same. For this reason, the blended composition during melting may be used as the composition of the obtained aluminum alloy sputtering target. However, it is preferable to confirm the composition of the actually obtained aluminum alloy sputtering target.

### (2) Rolling, Heat Treatment, Machining

The obtained ingot is rolled to have substantially the same thickness as that of an aluminum alloy sputtering target, which is intended to be obtained, thereby a rolled material (sheet material) is obtained. The Rolling may be, for example, cold-rolling. The obtained rolled material is subjected to heat treatment (annealing). For example, a heat treatment temperature is 240′C to 260′C, a holding time is 2 hours to 3 hours, and an atmosphere may be air atmosphere.

The rolled material after the heat treatment is subjected to machining, and thus an aluminum alloy sputtering target is obtained. Examples of the machining include cutting using a lathe or the like and round punching. After the machining, polishing may be further performed to smooth the surface, particularly the surface on which ions collide.

### EXAMPLES

The embodiments of the present invention will be more specifically described below by way of Examples, but the present invention is not limited to the following Examples. Various modifications can be appropriately made to these examples as long as they are adaptable to the above-mentioned and below-mentioned concepts, and thus all these modifications are included within the technical scope of the present invention.

### Examples 1 to 5

Using an Al raw material, a Ni raw material and a Nd raw material, the raw materials were blended such that the amount of Ni added was 0.01 to 0.04 atomic %, the amount of Nd added was 0.01 to 0.06 atomic % and the balance was Al (containing inevitable impurities), and thus a blended raw material (raw material for melting). Both of the Al raw material and the Ni raw material used had a purity of 99.98% by mass. The Nd raw material used had a purity of 99.5% by mass. This blended raw material was vacuum-melted and cast to obtain an aluminum alloy ingot with the same composition as that of the blended raw material.

The obtained ingot was cold-rolled to obtain a rolled material. Cold-rolling was performed such that a thickness before rolling was 100 mm and a thickness after rolling was 8 mm, that is, a rolling reduction was 92%. Then, the rolled material was heat-treated in the atmosphere at 250° C. for 2 hours. After cutting, the rolled material was subjected to grinding as machining and then processed into a shape of 004.8 mm×5 mmt to obtain an aluminum alloy sputtering target. It was confirmed that the composition of the obtained aluminum alloy sputtering target was the same as that of the blended raw material. Using the above-mentioned brazing material, the obtained aluminum alloy sputtering target was bonded to a backing plate made of pure Cu.

### Examples 6 to 9

In the same manner as in Example 1, except that the composition of the blended raw material was changed such that each amount of Cr, Fe, Co or Cu added was 0.02 atomic %, the amount of Nd added was 0.04 atomic % and the balance was Al (containing inevitable impurities), an aluminum alloy sputtering target was produced. It was confirmed that the composition of the obtained aluminum alloy sputtering target was the same as that of the blended raw material.

### Examples 10 to 25

In the same manner as in Example 1, except that the composition of the blended raw material was changed such that the amount of Ni added was 0.02 atomic %, the amount of each rare earth element (excluding La) was 0.04 atomic % and the balance was Al (containing inevitable impurities), an aluminum alloy sputtering target was produced. It was confirmed that the composition of the obtained aluminum alloy sputtering target was the same as that of the blended raw material.

### Comparative Example 1

In the same manner as in Example 1, except that the blended raw material was only the Al raw material, a pure aluminum sputtering target was produced.

### Comparative Example 2

In the same manner as in Example 1, except that the composition of the blended raw material was changed such that the amount of Ta added was 0.03 atomic %, the amount of Nd was 0.04 atomic % and the balance was Al (containing inevitable impurities), an aluminum alloy sputtering target was produced. It was confirmed that the composition of the obtained aluminum alloy sputtering target was the same as that of the blended raw material.

### Comparative Example 3

In the same manner as in Example 1, except that the composition of the blended raw material was changed such that the amount of Ni added was 0.02 atomic %, the amount of Ti was 0.04 atomic % and the balance was Al (containing inevitable impurities), an aluminum alloy sputtering target was produced. It was confirmed that the composition of the obtained aluminum alloy sputtering target was the same as that of the blended raw material.

### Comparative Example 4

In the same manner as in Example 1, except that the composition of the blended raw material was changed such that the amount of Ni added was 0.02 atomic %, the amount of La was 0.04 atomic % and the balance was Al (containing inevitable impurities), an aluminum alloy sputtering target was produced. It was confirmed that the composition of the obtained aluminum alloy sputtering target was the same as that of the blended raw material.

### [Observation of Flakes]

With respect to each of Examples 1 to 25 and Comparative Examples 1 to 4, a backing plate with the aluminum alloy sputtering target or the pure aluminum sputtering target bonded thereto was mounted on a magnetron DC sputtering apparatus, and then sputtering was performed under the conditions of DC 4.5 kW and a pressure of 0.3 Pa. Sputtering was performed for 250 seconds per time on a silicon substrate having a size of 4 inch to form an aluminum thin film having a thickness of 1,000 nm. The silicon substrate was exchanged for each film formation.

The silicon substrate after film formation was examined by an optical particle counter and positions where particles generated were observed by a microscope. The particles were observed to judge whether or not they are flakes according to the shape, and then the number of flakes per one silicon substrate was examined. An aluminum alloy sputtering target in which the number of flakes per one silicon substrate is 14 or less was determined to be a practicable level. The measurement results are shown in Table 1.

### [Measurement of Electric Resistivity]

With respect to each of Examples 1 to 25 and Comparative Examples 1 to 4, sputtering was performed in the same manner as mentioned above, using the aluminum alloy sputtering targets or the pure aluminum sputtering target, except that the film formation time was changed, an aluminum thin film having a thickness of 900 nm was formed. Next, a Mo thin film having a thickness of 70 nm was laminated as upper and lower layers thereof, and the resistivity of the aluminum thin film after being heated at 450° C. for 1 hour was measured. An aluminum alloy sputtering target, which could form an aluminum thin film whose electrical resistivity is 1.05 times or less the electrical resistivity of a pure aluminum thin film (Comparative Example 1), was determined to be a practicable level. The measurement results are shown in Table 1.

TABLE 1

| | | Number of flakes | Electric resistivity |
|---|---|---|---|
| | Composition of | per one silicon | of aluminum thin |
| | sputtering target | substrate | film (μΩ cm) |
| Example 1 | Al—0.01Ni—0.04Nd | 8 | 3.04 |
| Example 2 | Al—0.02Ni—0.01Nd | 10 | 3.04 |
| Example 3 | Al—0.02Ni—0.04Nd | 6 | 3.06 |
| Example 4 | Al—0.02Ni—0.06Nd | 4 | 3.12 |
| Example 5 | Al—0.04Ni—0.04Nd | 3 | 3.14 |
| Example 6 | Al—0.02Fe—0.04Nd | 6 | 3.09 |
| Example 7 | Al—0.02Co—0.04Nd | 5 | 3.05 |
| Example 8 | Al—0.02Cr—0.04Nd | 5 | 3.04 |
| Example 9 | Al—0.02Cu—0.04Nd | 14 | 3.14 |
| Example 10 | Al—0.02Ni—0.04Sc | 13 | 3.10 |
| Example 11 | Al—0.02Ni—0.04Y | 5 | 3.08 |
| Example 13 | Al—0.02Ni—0.04Ce | 4 | 3.04 |
| Example 14 | Al—0.02Ni—0.04Pr | 6 | 3.07 |
| Example 15 | Al—0.02Ni—0.04Pm | 5 | 3.06 |
| Example 16 | Al—0.02Ni—0.04Sm | 3 | 3.04 |
| Example 17 | Al—0.02Ni—0.04Eu | 9 | 3.08 |
| Example 18 | Al—0.02Ni—0.04Gd | 4 | 3.05 |
| Example 19 | Al—0.02Ni—0.04Tb | 6 | 3.08 |
| Example 20 | Al—0.02Ni—0.04Dy | 6 | 3.05 |
| Example 21 | Al—0.02Ni—0.04Yb | 10 | 3.11 |
| Example 22 | Al—0.02Ni—0.04Ho | 11 | 3.13 |
| Example 23 | Al—0.02Ni—0.04Er | 13 | 3.07 |
| Example 24 | Al—0.02Ni—0.04Tm | 14 | 3.14 |
| Example 25 | Al—0.02Ni—0.04Lu | 13 | 3.10 |
| Comparative Example 1 | Pure aluminum | 24 | 3.08 |
| Comparative Example 2 | Al—0.03Ta—0.04Nd | 18 | 3.24 |
| Comparative Example 3 | Al—0.02Ni—0.04Ti | 21 | 3.26 |
| Comparative Example 4 | Al—0.02Ni—0.04La | 15 | 3.05 |

All of Examples 1 to 25 are examples which satisfy all of requirements defined in the embodiment of the present invention, and the number of flakes per one silicon substrate was 20 or less and the electric resistivity of the aluminum thin film was 1.05 times or less the electric resistivity of the pure aluminum thin film (Comparative Example 1), and these examples exhibited the same level of conductivity as that of a conventional aluminum alloy sputtering target and could reduce the generation of flakes.

Among these examples, Example 1 to 8 containing 0.01 atomic % to 0.04 atomic % of at least one element selected from the group consisting of Ni, Cr, Fe or Co and 0.01 atomic % to 0.06 atomic % of Nd which is a rare earth element other than La, and Examples 11 to 21 containing 0.01 atomic % to 0.03 atomic % of at least one element selected from the group consisting of Ni, Cr, Fe or Co and 0.03 atomic % to 0.05 atomic % of at least one element selected from Y, Ce, Pr, Pm, Sm, Eu, Gd, Tb, Dy or Yb exhibited the number of flakes per one silicon substrate of 10 or less and could further reduce the generation of flakes.

Example 9 is an example containing Cu, and the amount of flakes generated was slightly larger than that of Examples 3 and 6 to 8 containing the same amount of Ni, Fe, Co or Cr instead of Cu. This is because the metallic bond radius (1.28 Å) of Cu is within 80 to 90% of the metallic bond radius (1.45 Å) of pure Al, but is 88% which is larger than that of other elements (Cr, Ni, Fe, Co).

Examples 10 and 22 to 25 are examples containing Sc, Ho, Er, Tm or Lu, and the amount of flakes generated was slightly larger than that of Examples 11 to 21 containing the same amount of Y, Ce, Pr, Pm, Sm, Eu, Gd, Tb, Dy or Yb instead of those elements. This is because the metallic bond radius of Sc, Ho, Er, Tm or Lu is within 110% or more of the metallic bond radius (1.45 Å) of pure Al, but is 112 to 120% which is larger than that of other rare earth elements (excluding La).

To the contrary, Comparative Example 1 is an example which does not contain elements other than A1 (containing inevitable impurities), and the number of flakes per one silicon substrate was 24, and a large number of flakes were generated.

Comparative Example 2 is an example containing Ta which is not defined in embodiments of the present invention, and the number of flakes per one silicon substrate was 18, and a large number of flakes were generated.

Comparative Example 3 is an example containing Ti which is not defined in embodiments of the present invention, and the number of flakes per one silicon substrate was 21, and a large number of flakes were generated. The electric resistivity of the aluminum thin film is 1.06 times the electric resistivity of the pure aluminum thin film (Comparative Example 1), and the conductivity was inferior.

Comparative Example 4 is an example containing La that is not defined in the embodiments of the present invention, and the number of flakes per one silicon substrate is 15, and a large number of flakes were generated.

The application claims priority based on Japanese Patent Application No. 2016-232069 filed on Nov. 30, 2016. Japanese Patent Application No. 2016-232069 is incorporated herein by reference.

1. An aluminum alloy sputtering target comprising;
A1;
0.01 atomic % to 0.04 atomic % in total of at least one element selected from the group consisting of Ni, Cr, Fe, Co and Cu, and
0.01 atomic % to 0.06 atomic % in total of at least one element selected from rare earth elements other than La.

2. The aluminum alloy sputtering target according to claim 1, wherein the rare earth elements are Y, Ce, Pr, Pm, Sm, Eu, Gd, Tb, Dy and Yb.

3. The aluminum alloy sputtering target according to claim 1, comprising:
0.01 atomic % to 0.03 atomic % in total of at least one element selected from the group consisting of Ni, Cr, Fe and Co, and
0.03 atomic % to 0.05 atomic % in total of at least one element selected from the group consisting of Y, Ce, Pr, Pm, Sm, Eu, Gd, Tb, Dy and Yb.

4. An electrode film formed by using the aluminum alloy sputtering target according to claim 1, comprising Al, 0.01 atomic % to 0.04 atomic % in total of at least one element selected from the group consisting of Ni, Cr, Fe, Co and Cu, and 0.01 atomic % to 0.06 atomic % in total of at least one element selected from rare earth elements other than La.

5. A thin film transistor comprising the electrode film according to claim 4.

6. A display device comprising the electrode film according to claim 4.

7. A display device comprising the thin film transistor according to claim 5.
